(19) United States
(12) Patent Application Publication
(10) Pub. No.: US 2025/0301806 A1
(43) Pub. Date: Sep. 25, 2025

(54) LIGHT SENSING DEVICE

(71) Applicant: TDK Corporation, Tokyo (JP)

(72) Inventors: Yusho HIRATA, Tokyo (JP); Tetsuya Shibata, Tokyo (JP); Hideaki Fukuzawa, Tokyo (JP)

(73) Assignee: TDK Corporation, Tokyo (JP)

(21) Appl. No.: 19/079,818

(22) Filed: Mar. 14, 2025

(30) Foreign Application Priority Data
Mar. 19, 2024 (JP) 2024-043941

(51) Int. Cl. H10F 30/10; H10F 77/40

(52) U.S. Cl. CPC H10F 30/10; H10F 77/413

(57) ABSTRACT

The light sensing device includes a first terminal, a second terminal, a third terminal, a fourth terminal, a first element, a second element, a third element, and a fourth element. The first terminal, the first element, the second element, and the second terminal form a first path. The first terminal, the third element, the fourth element, and the second terminal form a second path. The third terminal is connected between the first element and the second element. The fourth terminal is connected between the third element and the fourth element. Each of the first element, the second element, the third element, and the fourth element includes a photosensitive layer that. The photosensitive layer of the first element is irradiated with light to be measured. The photosensitive layers of the second element and the third element are not irradiated with the light to be measured.

### BACKGROUND OF THE INVENTION

### Field of the Invention

The present invention relates to a light sensing device.

### Description of Related Art

Photoelectric converters have been used for various purposes.

For example, Patent Document 1 discloses a receiver device that receives an optical signal using a photodiode. A photodiode is, for example, a pn junction diode using a pn junction of semiconductor and converts light to an electrical signal.

For example, Patent Document 2 discloses a novel optical device using a magnetic element. A magnetic state of a magnetic element changes and a resistance value thereof changes when the magnetic element is irradiated with light.

### PATENT DOCUMENTS

[Patent Document 1] Japanese Unexamined Patent Application, First Publication No. 2001-292107

[Patent Document 2] Japanese Unexamined Patent Application, First Publication No. 2023-90284

### SUMMARY OF THE INVENTION

An optical sensor converts light to an electrical signal. For example, an output of an optical sensor using a magnetic element may change due to an influence of disturbance such as temperature and magnetic fields. Accordingly, an influence of disturbance cannot be ignored in measuring a light intensity using an optical sensor, and there is need for a light sensing device that is less likely to be affected by disturbance.

The present invention was made in consideration of the aforementioned circumstances, and an objective thereof is to provide a light sensing device that is less likely to be affected by disturbance.

In order to achieve the aforementioned object, the following means are provided.

A light sensing device according to an embodiment includes a first terminal, a second terminal, a third terminal, a fourth terminal, a first element, a second element, a third element, and a fourth element. The first terminal, the first element, the second element, and the second terminal form a first path. The first terminal, the third element, the fourth element, and the second terminal form a second path. The third terminal is connected between the first element and the second element. The fourth terminal is connected between the third element and the fourth element. Each of the first element, the second element, the third element, and the fourth element includes a first electrode, a second electrode, and a photosensitive layer that is provided between the first electrode and the second electrode and generates a voltage in a case where light is applied to the photosensitive layer. The photosensitive layer of the first element is irradiated with light to be measured. The photosensitive layers of the second element and the third element are not irradiated with the light to be measured.

The light sensing device according to the aspect is less likely to be affected by disturbance.

### BRIEF DESCRIPTION OF THE DRAWINGS

FIG. 1 is a plan view of a light sensing device according to a first embodiment.

FIG. 2 is a sectional view of the vicinity of a first element of the light sensing device according to the first embodiment.

FIG. 3 is a sectional view of the vicinity of a second element of the light sensing device according to the first embodiment.

FIG. 4 is a diagram illustrating an operation example of the first element according to the first embodiment.

FIG. 5 is a diagram illustrating an operation example of the first element according to the first embodiment.

FIG. 6 is a sectional view of the vicinity of a second element of a light sensing device according to a first modified example of the first embodiment.

FIG. 7 is a sectional view of the vicinity of a second element of a light sensing device according to a second modified example of the first embodiment.

FIG. 8 is a plan view of a light sensing device according to a second embodiment.

FIG. 9 is a plan view of a light sensing device according to a third embodiment.

FIG. 10 is a plan view of a light sensing device according to a fourth embodiment.

FIG. 11 is a sectional view of the vicinity of a first element of the light sensing device according to the fourth embodiment.

FIG. 12 is a sectional view of the vicinity of a second element of the light sensing device according to the fourth embodiment.

FIG. 13 is a plan view of a light sensing device according to a fifth embodiment.

FIG. 14 is a plan view of a light sensing device according to a sixth embodiment.

FIG. 15 is a diagram schematically illustrating an optical unit according to a first application example.

FIG. 16 is a conceptual diagram of an optical system using the optical unit according to the first application example.

FIG. 17 is a diagram schematically illustrating a transceiver device according to a second application example.

FIG. 18 is a conceptual diagram illustrating an example of a communication system.

FIG. 19 is a conceptual diagram illustrating another example of the communication system.

### DETAILED DESCRIPTION OF THE INVENTION

Hereinafter, an embodiment will be described in detail with appropriate reference to the accompanying drawings. In the drawings used in the following description, featured parts may be conveniently enlarged for the purpose of easy understanding of features, and dimensions, ratios, and the like of constituents may be different from actual ones. Materials, dimensions, and the like exemplified in the following description are merely examples, and the present invention is not limited thereto and can be appropriately modified within ranges in which the advantageous effects of the present invention can be achieved.

Directions are defined. One in-plane direction of a plane in which layers extend is defined as an X direction, and a direction perpendicular to the X direction in the plane is defined as a Y direction. A stacking direction perpendicular to the layers is defined as a Z direction. In the following description, the +Z direction may be referred to as “upward,” and the −Z direction may be referred to as “downward.” The +Z direction is a direction directed from a second electrode 22 to a first electrode 21. Upward and downward do not necessarily match a direction in which a gravitational force is applied.

### First Embodiment

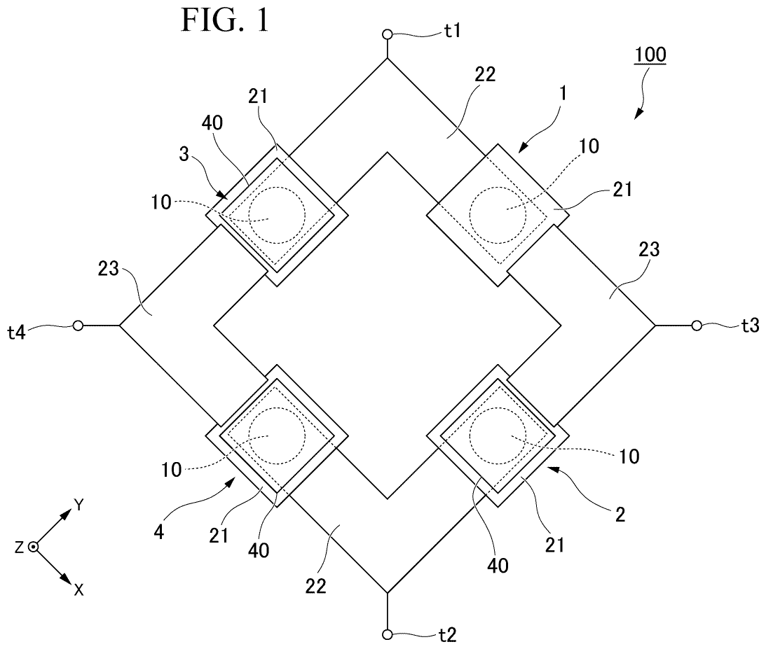

FIG. 1 is a plan view of a light sensing device 100 according to a first embodiment. The light sensing device 100 includes a first terminal t1, a second terminal t2, a third terminal t3, a fourth terminal t4, a first element 1, a second element 2, a third element 3, and a fourth element 4.

The first terminal t1 is connected to, for example, a power supply. The first terminal t1 is connected to the first element 1 and the third element 3. The second terminal t2 is connected to, for example, a reference potential. The reference potential is, for example, a ground potential. The second terminal t2 is connected to the second element 2 and the fourth element 4.

Two current paths are formed between the first terminal t1 and the second terminal t2. The first path is a path connecting the first terminal t1, the first element 1, the second element 2, and the second terminal t2. The second path is a path connecting the first terminal t1, the third element 3, the fourth element 4, and the second terminal t2. The first path and the second path are electrically parallel each other.

The third terminal t3 is connected to the first element 1 and the second element 2. The third terminal t3 is connected to an upper electrode 23 that electrically connects the first element 1 and the second element 2. The fourth terminal t4 is connected to the third element 3 and the fourth element 4. The fourth terminal t4 is connected to an upper electrode 23 that electrically connects the third element 3 and the fourth element 4. The light sensing device 100 measures a potential difference between the third terminal t3 and the fourth terminal t4.

The first element 1, the second element 2, the third element 3, and the fourth element 4 are optical sensors. In the following description, the first element 1, the second element 2, the third element 3, and the fourth element 4 are collectively referred to as optical sensors when they are not distinguished from each other. The first element 1 is electrically provided between the first terminal t1 and the third terminal t3. The second element 2 is electrically provided between the third terminal t3 and the second terminal t2. The third element 3 is electrically provided between the first terminal t1 and the fourth terminal t4. The fourth element 4 is electrically provided between the fourth terminal t4 and the second terminal t2.

The first element 1, the second element 2, the third element 3, and the fourth element 4 are arranged such that they are in a spot of light to be applied to the light sensing device 100. The spot is a range in which an irradiation subject is irradiated with light. The spot is a continuous area including a center and is a range in which light with an intensity of equal to or greater than 13.5% of a light intensity at the center is applied. The range of the spot of light is determined by optical members. The optical members include, for example, a waveguide, a lens, and a light source.

Light L is not limited to visible light and includes infrared light of a longer wavelength than visible light and ultraviolet light of a shorter wavelength than visible light. The wavelength of the visible light is, for example, equal to or greater than 380 nm and less than 800 nm. The wavelength of the infrared light is, for example, equal to or greater than 800 nm and less than 1 mm. The wavelength of the ultraviolet light is, for example, equal to or greater than 200 nm and equal to or less than 380 nm. For example, the light may be light with a varying intensity including a high-frequency optical signal or light of which a wavelength range is controlled (for example, light having passed through a wavelength filter). The high-frequency optical signal is, for example, a signal with a frequency equal to or higher than 100 MHz.

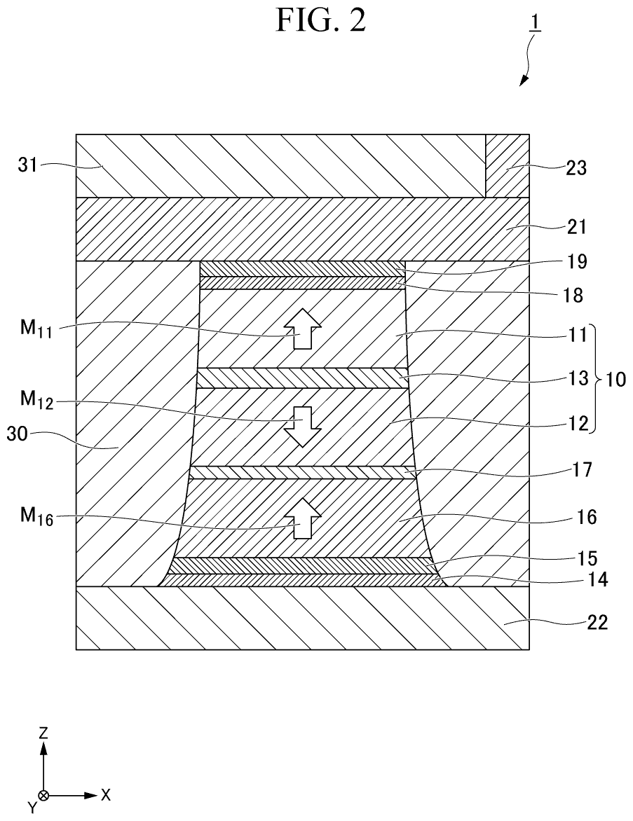

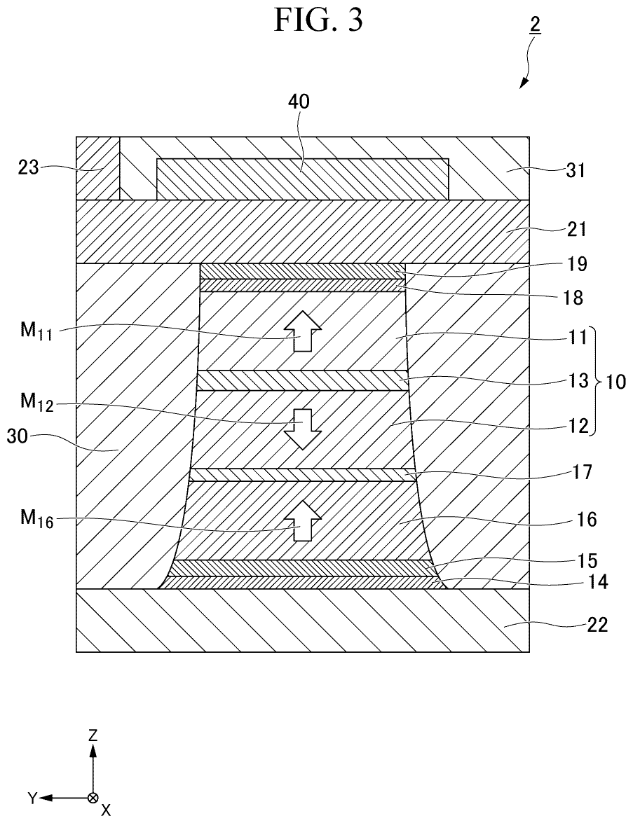

FIG. 2 is a sectional view of the vicinity of the first element 1 of the light sensing device 100 according to the first embodiment. FIG. 3 is a sectional view of the vicinity of the second element 2 of the light sensing device 100 according to the first embodiment. The third element 3 and the fourth element 4 have the same configuration as the second element 2, and thus illustration thereof is omitted.

Each of the first element 1, the second element 2, the third element 3, and the fourth element 4 includes a first electrode 21, a second electrode 22, and a photosensitive layer 10. The photosensitive layer 10 is provided between the first electrode 21 and the second electrode 22.

Each of the first element 1, the second element 2, the third element 3, and the fourth element 4 may further include a buffer layer 14, a seed layer 15, a third ferromagnetic layer 16, a magnetic coupling layer 17, a perpendicular magnetization inducing layer 18, a cap layer 19, an insulating layer 30, and an insulating layer 31. The buffer layer 14, the seed layer 15, the third ferromagnetic layer 16, and the magnetic coupling layer 17 are located between the photosensitive layer 10 and the second electrode 22, and the perpendicular magnetization inducing layer 18 and the cap layer 19 are located between the photosensitive layer 10 and the first electrode 21. The insulating layer 30 is located between the first electrode 21 and the second electrode 22 and covers a laminate including the photosensitive layer 10. The insulating layer 31 covers the top of the first electrode 21. The insulating layer 31 may be omitted.

The photosensitive layer 10 generates a voltage when it is irradiated with light. When the state of light applied thereto changes, a resistance value in the Z direction of the photosensitive layer 10 changes with the change in the state of light. When the state of light applied to the photosensitive layer 10 changes, an output voltage from an optical sensor changes with the change in the state of light. The photosensitive layer 10 includes, for example, a first ferromagnetic layer 11, a second ferromagnetic layer 12, and a spacer layer 13. The spacer layer 13 is located between the first ferromagnetic layer 11 and the second ferromagnetic layer 12. The photosensitive layer 10 may include other layers.

The photosensitive layer 10 is a magnetic element including a ferromagnetic substance. For example, when the spacer layer 13 is formed of an insulator, the photosensitive layer 10 includes a magnetic tunnel junction (MTJ) which is constituted by the first ferromagnetic layer 11, the spacer layer 13, and the second ferromagnetic layer 12. This element is referred to as an MTJ element. In this case, the photosensitive layer 10 can exhibit a tunnel magnetoresistance (TMR) effect. When the spacer layer 13 is formed of a metal, the photosensitive layer 10 can exhibit a giant magnetoresistance (GMR) effect. This element is referred to as a GMR element. The photosensitive layer 10 is referred to as different names such as an MTJ element and a GMR element according to the material of the spacer layer 13 and is also collectively referred to as a magnetoresistance effect element. A resistance value in the Z direction (a resistance value when a current flows in the Z direction) of the photosensitive layer 10 changes according to a relative change of a magnetization M₁₁ state of the first ferromagnetic layer 11 and a magnetization M₁₂ state of the second ferromagnetic layer 12.

The first ferromagnetic layer 11 is a light sensing layer in which a magnetization state changes when light is externally applied thereto. The first ferromagnetic layer 11 is also referred to as a magnetization free layer. The magnetization free layer is a layer including a magnetic substance in which a magnetization state changes when predetermined energy is externally applied thereto. The predetermined energy from the outside includes, for example, light which is applied from the outside, a current which flows in the Z direction of the photosensitive layer 10, and an external magnetic field. The magnetization M₁₁ state of the first ferromagnetic layer 11 changes according to an intensity of light applied to the first ferromagnetic layer 11 (light applied to the photosensitive layer 10).

The first ferromagnetic layer 11 includes a ferromagnetic substance. The first ferromagnetic layer 11 includes, for example, at least one of magnetic elements such as Co, Fe, and Ni. The first ferromagnetic layer 11 may include elements such as B, Mg, Hf, and Gd in addition to the aforementioned magnetic elements. The first ferromagnetic layer 11 may be formed of, for example, an alloy including a magnetic element and a nonmagnetic element. The first ferromagnetic layer 11 may include a plurality of layers. The first ferromagnetic layer 11 is, for example, a CoFeB alloy layer, a laminate in which a CoFeB alloy layer is interposed between Fe layers, or a laminate in which a CoFeB alloy layer is interposed between CoFe layers. In general, “ferromagnetism” includes “ferrimagnetism.” The first ferromagnetic layer 11 may exhibit ferrimagnetism. On the other hand, the first ferromagnetic layer 11 may exhibit ferromagnetism other than ferrimagnetism. For example, the CoFeB alloy exhibits ferromagnetism other than ferrimagnetism.

The first ferromagnetic layer 11 may be an in-plane magnetized film having an easy magnetization axis in an in-plane direction (some directions in the xy plane) or may be a perpendicularly magnetized film including an easy magnetization axis in a plane-perpendicular direction (the Z direction).

The thickness of the first ferromagnetic layer 11 is, for example, equal to or greater than 1 nm and equal to or less than 5 nm. For example, it is preferable that the thickness of the first ferromagnetic layer 11 be equal to or greater than 1 nm and equal to or less than 2 nm. When the first ferromagnetic layer 11 is a perpendicularly magnetized film and the thickness of the first ferromagnetic layer 11 is small, a perpendicular magnetic anisotropy application effect from layers located on and below the first ferromagnetic layer 11 is strengthened, and the perpendicular magnetic anisotropy is enhanced. That is, when the perpendicular magnetic anisotropy of the first ferromagnetic layer 11 is high, a force for returning magnetization M₁₁ in the Z direction is increased. On the other hand, when the thickness of the first ferromagnetic layer 11 is large, the perpendicular magnetic anisotropy application effect from layers located on and below the first ferromagnetic layer 11 is weakened, and the perpendicular magnetic anisotropy application effect from layers located on and below the first ferromagnetic layer 11 of the first ferromagnetic layer 11 is weakened.

When the thickness of the first ferromagnetic layer 11 decreases, a volume serving as a ferromagnetic substance decreases. When the thickness of the first ferromagnetic layer 11 increases, the volume serving as a ferromagnetic substance increases. Magnetization M₁₁ reactivity of the first ferromagnetic layer 11 is inversely proportional to a product (KuV) of the magnetic anisotropy (Ku) and the volume of the first ferromagnetic layer 11. That is, when the product of the magnetic anisotropy and the volume of the first ferromagnetic layer 11 decreases, the reactivity to light increases. From this viewpoint, it is preferable to appropriately design the magnetic anisotropy of the first ferromagnetic layer 11 and to decrease the volume of the first ferromagnetic layer 11 in order to increase the reactivity to light.

When the thickness of the first ferromagnetic layer 11 is larger than 2 nm, for example, an insertion layer formed of Mo or W may be provided in the first ferromagnetic layer 11. That is, a laminate in which a ferromagnetic layer, an insertion layer, and a ferromagnetic layer are sequentially stacked in the Z direction may be used as the first ferromagnetic layer 11. The perpendicular magnetic anisotropy of the first ferromagnetic layer 11 as a whole is increased by interface magnetic anisotropy at an interface between the insertion layer and the ferromagnetic layer. The thickness of the insertion layer ranges, for example, from 0.1 nm to 1.0 nm.

The second ferromagnetic layer 12 is a magnetization fixed layer. The magnetization fixed layer is a layer formed of a magnetic substance in which a state of magnetization M₁₂ is less likely to change than the magnetization free layer when predetermined energy is externally applied thereto. For example, a magnetization direction of the magnetization fixed layer is less likely to change than that of the magnetization free layer when predetermined energy is externally applied thereto. For example, a magnetization magnitude of the magnetization fixed layer is less likely to change than that of the magnetization free layer when predetermined energy is externally applied thereto. For example, a coercive force of the second ferromagnetic layer 12 is larger than a coercive force of the first ferromagnetic layer 11. The second ferromagnetic layer 12 includes, for example, an easy magnetization axis of the same direction as the first ferromagnetic layer 11. The second ferromagnetic layer 12 may be an in-plane magnetized film or a perpendicularly magnetized film.

For example, the material of the second ferromagnetic layer 12 is the same as the first ferromagnetic layer 11. The second ferromagnetic layer 12 may be, for example, a multi-layered layer in which Co with a thickness of 0.4 nm to 1.0 nm and Pt with a thickness of 0.4 nm to 1.0 nm are alternately stacked by several turns. The second ferromagnetic layer 12 may be, for example, a laminate in which Co with a thickness of 0.4 nm to 1.0 nm, Mo with a thickness of 0.1 nm to 0.5 nm, a CoFeB alloy with a thickness of 0.3 nm to 1.0 nm, and Fe with a thickness of 0.3 nm to 1.0 nm are alternately stacked.

The magnetization M₁₂ of the second ferromagnetic layer 12 may be fixed, for example, by magnetic coupling to magnetization M₁₆ of the third ferromagnetic layer 16. In this case, the second ferromagnetic layer 12, the magnetic coupling layer 17, and the third ferromagnetic layer 16 may be collectively referred to as a magnetization fixed layer. Details of the magnetic coupling layer 17 and the third ferromagnetic layer 16 will be described later.

The spacer layer 13 is a layer which is disposed between the first ferromagnetic layer 11 and the second ferromagnetic layer 12. The spacer layer 13 is constituted by a layer formed of a conductor, an insulator, or a semiconductor or a layer including a conductive spot formed of a conductor in an insulator. The spacer layer 13 is, for example, a nonmagnetic layer. The thickness of the spacer layer 13 can be adjusted according to alignment directions of the magnetization M₁₁ of the first ferromagnetic layer 11 and the magnetization M₁₂ of the second ferromagnetic layer 12 in an initial state which will be described later.

When the spacer layer 13 is formed of an insulating material, a material including aluminum oxide, magnesium oxide, titanium oxide, or silicon oxide can be used as the material of the spacer layer 13. This insulating material may include an element such as Al, B, Si, or Mg or a magnetic element such as Co, Fe, or Ni. By adjusting the thickness of the spacer layer 13 such that a high TME effect is exhibited between the first ferromagnetic layer 11 and the second ferromagnetic layer 12, a high magnetoresistance change rate is obtained. In order to efficiently use the TMR effect, the thickness of the spacer layer 13 may be set to about 0.5 nm to 5.0 nm or about 1.0 nm to 2.5 nm.

When the spacer layer 13 is formed of a nonmagnetic conductive material, a conductive material such as Cu, Ag, Au, or Ru can be used. In order to efficiently use the GMR effect, the thickness of the spacer layer 13 may be set to about 0.5 nm to 5.0 nm or about 2.0 nm to 3.0 nm.

When the spacer layer 13 is formed of a nonmagnetic semiconductor material, a material such as zinc oxide, indium oxide, tin oxide, germanium oxide, gallium oxide, or ITO can be used. In this case, the thickness of the spacer layer 13 may be set to 1.0 nm to 4.0 nm.

When a layer including a conductive spot formed of a conductor in a nonmagnetic insulator is used as the spacer layer 13, a structure in which a conductive spot formed of a nonmagnetic conductor such as Cu, Au, or Al is included in a nonmagnetic insulator formed of aluminum oxide or magnesium oxide may be employed. The conductor may include a magnetic element such as Co, Fe, or Ni. In this case, the thickness of the spacer layer 13 may be set to 1.0 nm to 2.5 nm. The conductive spot is, for example, a columnar member with a diameter of 1 nm to 5 nm when seen in a direction perpendicular to a film plane.

The third ferromagnetic layer 16 is magnetically coupled to, for example, the second ferromagnetic layer 12. Magnetic coupling is, for example, antiferromagnetic coupling and is caused by an RKKY interaction. The material of the third ferromagnetic layer 16 is, for example, the same as the first ferromagnetic layer 11.

The magnetic coupling layer 17 is located between the second ferromagnetic layer 12 and the third ferromagnetic layer 16. The magnetic coupling layer 17 is formed of, for example, Ru or Ir.

The buffer layer 14 is a layer for buffering lattice mismatch between different crystals. The buffer layer 14 is, for example, a metal including at least one type of element selected from a group consisting of Ta, Ti, Zr, and Cr or a nitride including at least one type of element selected from a group consisting of Ta, Ti, Zr, and Cu. More specifically, the buffer layer 14 is formed of, for example, Ta (simple substance), an NiCr alloy, tantalum nitride (TaN), or copper nitride (CuN). The thickness of the buffer layer 14 is, for example, equal to or greater than 1 nm and equal to or less than 5 nm. The buffer layer 14 is, for example, amorphous. For example, the buffer layer 14 is located between the seed layer 15 and the second electrode 22 and is in contact with the second electrode 22. The buffer layer 14 curbs an influence of a crystal structure of the second electrode 22 on a crystal structure of the photosensitive layer 10.

The seed layer 15 increases crystallizability of a layer which is stacked on the seed layer 15. For example, the seed layer 15 is located between the buffer layer 14 and the third ferromagnetic layer 16 and is located on the buffer layer 14. The seed layer 15 is formed of, for example, Pt, Ru, Zr, or NiFeCr. The thickness of the seed layer 15 is, for example, equal to or greater than 1 nm and equal to or less than 5 nm.

The cap layer 19 is located between the first ferromagnetic layer 11 and the first electrode 21. The cap layer 19 may include a perpendicular magnetization inducing layer 18 which is stacked on the first ferromagnetic layer 11 and which is in contact with the first ferromagnetic layer 11. The cap layer 19 prevents damage on an underlying layer in the course of processing and enhances crystallizability at the time of annealing. The thickness of the cap layer 19 is, for example equal to or less than 10 nm such that sufficient light is applied to the first ferromagnetic layer 11.

The perpendicular magnetization inducing layer 18 induces perpendicular magnetic anisotropy of the first ferromagnetic layer 11. The perpendicular magnetization inducing layer 18 is formed of, for example, magnesium oxide, W, Ta, or Mo. When the perpendicular magnetization inducing layer 18 is formed of magnesium oxide, it is preferable that magnesium oxide be deficient in oxygen in order to enhance conductivity. The thickness of the perpendicular magnetization inducing layer 18 is, for example, equal to or greater than 0.5 nm and equal to or less than 5.0 nm.

The insulating layers 30 and 31 are formed of, for example, oxides, nitrides, or oxynitrides of Si, Al, or Mg. The insulating layers 30 and 31 are formed of, for example, silicon oxide (SiOₓ), silicon nitride (SiNₓ), silicon carbide (SiC), chromium nitride, silicon carbo-nitride (SiCN), silicon oxynitride (SiON), aluminum oxide (Al₂O₃), or zirconium oxide (ZrOₓ).

The first electrode 21 is disposed on a side on which incident light is incident on the optical sensor. Incident light is applied from the first electrode 21 side to the photosensitive layer 10. The first electrode 21 is formed of a conductive material. The first electrode 21 is, for example, a transparent electrode having transmissivity to light in a use wavelength band. For example, it is preferable that the first electrode 21 transmit 80% or more of light in the use wavelength band. The use wavelength band of light is, for example, equal to or greater than 300 nm and equal to or less than 2 μm, preferably equal to or greater than 400 nm and equal to or less than 1500 nm, and more preferably equal to or greater than 400 nm and equal to or less than 800 nm. The first electrode 21 is formed of, for example, oxides such as indium tin oxide (ITO), indium zinc oxide (IZO), zinc oxide (ZnO), or indium gallium zinc oxide (IGZO). The first electrode 21 may have a structure in which a plurality of columnar metals are provided in a transparent electrode material of oxides. The first electrode 21 may include an antireflection film on an irradiation surface which is irradiated with light.

The second electrode 22 is formed of a conductive material. The second electrode 22 is formed of, for example, metal such as Cu, Al, or Au. Ta or Ti may be stacked on or under the metal. A stacked film of Cu and Ta, a stacked film of Ta, Cu, and Ti, or a stacked film of Ta, Cu, and TaN may be used as the second electrode 22. TiN or TaN may be used as the second electrode 22.

The second electrode 22 may be formed of, for example, a metal including at least one element selected from a group constituting of ruthenium, molybdenum, and tungsten. The second electrode 22 may be a single-layered film of one of ruthenium, molybdenum, and tungsten or may be a stacked film including a layer of at least one of ruthenium, molybdenum, and tungsten. Ruthenium, molybdenum, and tungsten have high melting points (equal to or higher than 2000° C.) and high thermal resistance. The second electrode 22 including these elements is not likely to deteriorate even when heat treatment for crystalizing a laminate including the photosensitive layer 10 and heat treatment in the semiconductor process are performed thereon.

The second electrode 22 reflects a part of incident light which is incident from the first electrode 21 side at an interface with a layer in contact with the second electrode 22 (an interface between the buffer layer 14 and the second electrode 22 and an interface between the insulating layer 30 and the second electrode 22). Ruthenium, molybdenum, and tungsten have a high light reflectance at the interfaces and a high reflectance of light in a wavelength range equal to or greater than 400 nm and equal to or less than 1500 nm at the interfaces. Reflected light reflected by the second electrode 22 is applied to the photosensitive layer 10. Since the second electrode 22 is formed of a predetermined material (a metal including at least one element selected from the group consisting of ruthenium, molybdenum, and tungsten), more incident light is reflected than when the second electrode 22 is formed of a material other than the predetermined material. Accordingly, an amount of light applied to the photosensitive layer 10 in the optical sensor is large.

The upper electrode 23 is formed of a conductive material. The upper electrode 23 is formed of, for example, aluminum, silver, or copper. The upper electrode 23 electrically connects the first electrode 21 of the first element 1 and the first electrode 21 of the second element 2. The upper electrode 23 electrically connects the first electrode 21 of the third element 3 and the first electrode 21 of the fourth element 4.

The second element 2, the third element 3, and the fourth element 4 include a light reflecting layer 40. On the other hand, the first element 1 does not include a light reflecting layer 40. When seen in the Z direction, the light reflecting layers 40 are located at positions overlapping the photosensitive layers 10 of the second element 2, the third element 3, and the fourth element 4. When seen in the Z direction, the light reflecting layers 40 cover photosensitive layers 10 of the second element 2, the third element 3, and the fourth element 4.

The light reflecting layer 40 reflects light applied to the optical sensor. The light reflecting layer 40 is formed of, for example, gold, silver, or copper. Since the first element 1 does not include the light reflecting layer 40, the photosensitive layer 10 of the first element 1 is irradiated with light to be measured. The first element 1 converts a state of light applied to the first element 1 or a change of the state to an electrical signal. Since the second element 2, the third element 3, and the fourth element 4 include the light reflecting layer 40, the photosensitive layers 10 of the second element 2, the third element 3, and the fourth element 4 are not irradiated with light to be measured.

The optical sensor is manufactured through a stacking step, an annealing step, and a processing step for each layer. First, the buffer layer 14, the seed layer 15, the third ferromagnetic layer 16, the magnetic coupling layer 17, the second ferromagnetic layer 12, the spacer layer 13, the first ferromagnetic layer 11, the perpendicular magnetization inducing layer 18, and the cap layer 19 are sequentially stacked on the second electrode 22. The layers are formed, for example, by sputtering.

Subsequently, the stacked film is annealed. The annealing temperature is, for example, equal to or higher than 250° C. and equal to or lower than 400° C. Thereafter, the stacked film is processed into a laminate with a columnar shape through photolithography and etching. The laminate may be a circular pillar or a polygonal pillar. For example, a shortest width of the laminate when seen in the Z direction is equal to or greater than 10 nm and equal to or less than 1000 nm.

Subsequently, the insulating layer 30 is formed to cover the side surfaces of the laminate. The insulating layer 30 may be stacked a plurality of times. Subsequently, the top surface of the cap layer 19 is exposed from the insulating layer 30 through chemical mechanical polishing, and the first electrode 21 is formed on the cap layer 19.

Subsequently, in the second element 2, the third element 3, and the fourth element 4, the light reflecting layers 40 are provided at the positions overlapping the photosensitive layers 10 of the elements when seen in the Z direction. The insulating layer 31 is formed to cover the first electrode 21 and the light reflecting layer 40. The upper electrode 23 electrically connecting the first element 1 and the second element 2 and electrically connecting the third element 3 and the fourth element 4 are formed therebetween. Through these steps, the light sensing device 100 is obtained.

The operations of the light sensing device 100 will be described below. First, the operation of the first element 1 will be described. A resistance value in the Z direction of the first element 1 changes with a change in intensity of light applied to the photosensitive layer 10.

When the intensity of light applied to the photosensitive layer 10 of the first element 1 changes from a first intensity to a second intensity, the resistance value in the Z direction of the first element 1 changes. The first intensity may be an intensity when the intensity of light applied to the photosensitive layer 10 is zero.

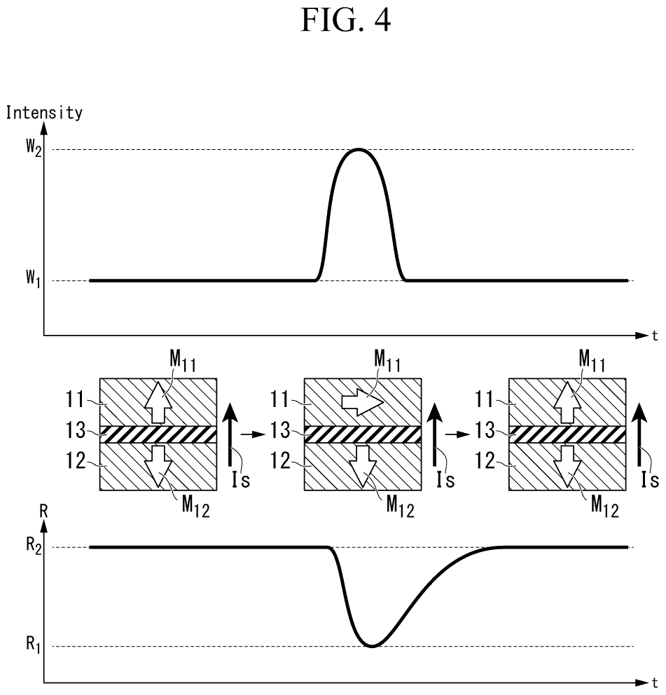

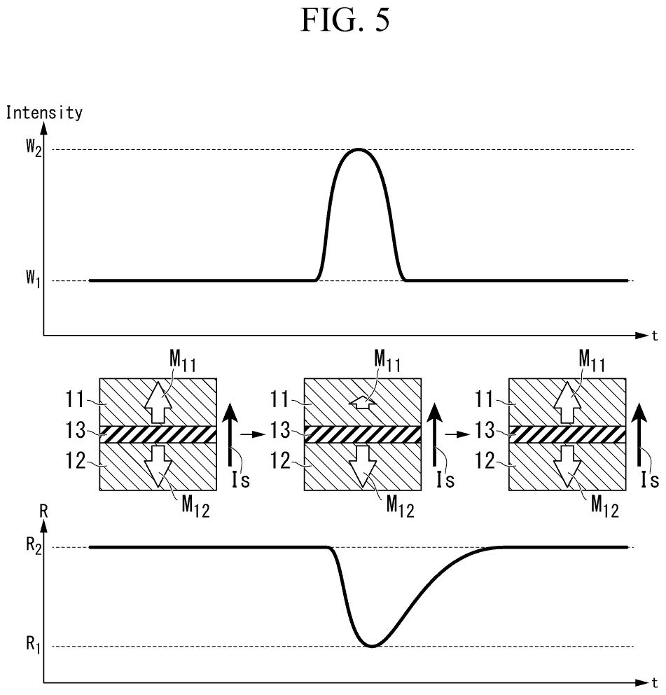

FIGS. 4 and 5 are diagrams illustrating an operation example of the first element 1 according to the first embodiment. FIG. 4 is a diagram illustrating a first mechanism of the operation example, and FIG. 5 is a diagram illustrating a second mechanism of the operation example. In the upper graphs of FIGS. 4 and 5, the vertical axis represents an intensity of light applied to the first ferromagnetic layer 11, and the horizontal axis represents time. In the lower graphs of FIGS. 4 and 5, the vertical axis represents a resistance value in the Z direction of the first element 1, and the horizontal axis represents time.

First, in a state (hereinafter referred to as an initial state) in which light with a first intensity W₁ is applied to the first ferromagnetic layer 11, the magnetization M₁₁ of the first ferromagnetic layer 11 and the magnetization M₁₂ of the second ferromagnetic layer 12 are anti-parallel to each other, and the resistance value in the Z direction of the first element 1 indicates a second resistance value R₂. Here, a state in which the intensity of light applied to the first ferromagnetic layer 11 is zero may be defined as a state in which light with the first intensity W₁ is applied.

By allowing a sensing current Is to flow in the Z direction of the first element 1, a voltage is generated across terminals in the Z direction of the first element 1. The output voltage from the first element 1 is generated between the first electrode 21 and the second electrode 22.

In the example illustrated in FIG. 4, it is preferable that the sensing current Is flow from the second ferromagnetic layer 12 to the first ferromagnetic layer 11. By allowing the sensing current Is to flow in this direction, a spin transfer torque in a direction opposite to the magnetization M₁₂ of the second ferromagnetic layer 12 acts on the magnetization M₁₁ of the first ferromagnetic layer 11, and the magnetization M₁₁ and the magnetization M₁₂ in the initial state are likely to be antiparallel to each other.

Subsequently, the intensity of light applied to the first ferromagnetic layer 11 changes from the first intensity W₁ to the second intensity W₂. For example, when a light pulse is applied to the photosensitive layer 10, the intensity of light applied to the first ferromagnetic layer 11 changes from the first intensity W₁ to the second intensity W₂. Light with the second intensity W₂ has a larger intensity than light with the first intensity W₁.

The second intensity W₂ is larger than the first intensity W₁, and the magnetization M₁₁ of the first ferromagnetic layer 11 changes from the initial state. The state of the magnetization M₁₁ of the first ferromagnetic layer 11 in a state in which light is not applied to the first ferromagnetic layer 11 and the state of the magnetization M₁₁ of the first ferromagnetic layer 11 in a state in which light with the second intensity W₂ is applied thereto are different from each other. The state of the magnetization M₁₁ includes, for example, a tilt angle with respect to the Z direction and a magnitude.

For example, when the intensity of light applied to the first ferromagnetic layer 11 changes from the first intensity W₁ to the second intensity W₂ as illustrated in FIG. 4, the magnetization M₁₁ is tilted with respect to the Z direction. For example, when the intensity of light applied to the first ferromagnetic layer 11 changes from the first intensity W₁ to the second intensity W₂ as illustrated in FIG. 5, the magnitude of the magnetization M₁₁ decreases. For example, when the magnetization M₁₁ of the first ferromagnetic layer 11 is tilted with respect to the Z direction according to the intensity of the applied light, the tilt angle is, for example, greater than 0° and less than 90°.

When the magnetization M₁₁ of the first ferromagnetic layer 11 changes from the initial state with application of a light pulse to the photosensitive layer 10, the resistance value in the Z direction of the first element 1 indicates the first resistance value R₁, and the output voltage from the first element 1 changes from a first value to a second value. As a result, the output from the light sensing device 100 (a potential difference between the third terminal t3 and the fourth terminal t4) changes. The first resistance value R₁ is less than the second resistance value R₂. The second value is less than the first value. The first resistance value R₁ is a value between a resistance value (the second resistance value R₂) when the magnetization M₁₁ and the magnetization M₁₂ are antiparallel and a resistance value when the magnetization M₁₁ and the magnetization M₁₂ are parallel.

In the example illustrated in FIG. 4, a spin transfer torque in a direction which is opposite to the magnetization M₁₂ of the second ferromagnetic layer 12 acts on the magnetization M₁₁ of the first ferromagnetic layer 11. Accordingly, the magnetization M₁₁ is going to return to the state in which it is antiparallel to the magnetization M₁₂, and the magnetization M₁₁ returns to the state in which it is antiparallel to the magnetization M₁₂ when the intensity of light applied to the first ferromagnetic layer 11 changes from the second intensity to the first intensity. In the example illustrated in FIG. 5, when the intensity of light applied to the first ferromagnetic layer 11 returns to the first intensity W₁, the magnitude of the magnetization M₁₁ of the first ferromagnetic layer 11 returns to the original magnitude, and the first element 1 returns to the initial state. In any case, the resistance value in the Z direction of the first element 1 returns to the second resistance value R₂. That is, when the intensity of light applied to the first ferromagnetic layer 11 changes from the second intensity W₂ to the first intensity W₁, the resistance value in the Z direction of the first element 1 changes from the first resistance value R₁ to the second resistance value R₂.

An example in which the magnetization M₁₁ and the magnetization M₁₂ in the initial state are antiparallel has been described above, but the magnetization M₁₁ and the magnetization M₁₂ in the initial state may be parallel. In this case, the resistance value in the Z direction of the first element 1 increases as the state of the magnetization M₁₁ changes (for example, as a change in angle from the initial state of the magnetization M₁₁ increases). When the initial state is a state in which the magnetization M₁₁ and the magnetization M₁₂ are parallel, it is preferable that the sensing current Is flow from the first ferromagnetic layer 11 to the second ferromagnetic layer 12. By allowing the sensing flow Is to flow in this direction, a spin transfer torque which has the same direction as the magnetization M₁₂ of the second ferromagnetic layer 12 acts on the magnetization M₁₁ of the first ferromagnetic layer 11, and the magnetization M₁₁ and the magnetization M₁₂ in the initial state are parallel.

An example in which light applied to the photosensitive layer 10 has two levels of the first intensity and the second intensity has been described above, but the intensity of light applied to the photosensitive layer 10 may change at more levels or in an analog manner. In this case, the resistance value of the first element 1 changes at the more levels or in an analog manner.

On the other hand, the photosensitive layers 10 of the second element 2, the third element 3, and the fourth element 4 are not irradiated with light to be measured. Accordingly, the resistance value in the Z direction of each of the second element 2, the third element 3, and the fourth element 4 does not change with application of light to be measured. On the other hand, the resistance value of each of the second element 2, the third element 3, and the fourth element 4 changes due to an influence of disturbance. Disturbance includes, for example, a change in temperature and a change in magnetic field. The second element 2, the third element 3, and the fourth element 4 are in the same environment as the first element 1 and are affected by the same disturbance. For example, when the light sensing device 100 is irradiated with laser light, the first element 1, the second element 2, the third element 3, and the fourth element 4 are disposed in one laser spot and thus cause the same change in temperature.

In the light sensing device 100, the first element 1, the second element 2, the third element 3, and the fourth element 4 form a bridge circuit. Accordingly, when the resistance value of the first element 1 is defined as R_{A}, the resistance value of the second element 2 is defined as R_{B}, the resistance value of the third element 3 is defined as R_{C}, and the resistance value of the fourth element 4 is defined as R_{D}, a relationship of R_{C}/R_{D}=R_{A}/R_{B} is satisfied when the potential difference between the third terminal t3 and the fourth terminal t4 is 0. When disturbance occurs in the first element 1, the second element 2, the third element 3, and the fourth element 4, R_{A}, R_{B}, R_{C}, and R_{D} change in the same way. In the relationship, influences of disturbance in the elements cancel each other. That is, the light sensing device 100 according to the present embodiment can cancel influences of disturbance as a whole and is less likely to be affected by the disturbance.

The output voltage from the light sensing device 100 (the potential difference between the third terminal t3 and the fourth terminal t4) changes with a change of the intensity of light applied to the photosensitive layer 10 of the first element 1, and the change of the intensity of the applied light can be converted to a change of the output voltage from the light sensing device 100. That is, the light sensing device 100 can convert light to an electrical signal. For example, a signal when the output voltage from the light sensing device 100 is equal to or greater than a threshold value is defined as a first signal (for example, “1”), and a signal when the output voltage is less than the threshold value is defined as a second signal (for example, “0”).

While an example of the present invention has been described above in conjunction with the first embodiment, the present invention is not limited to the embodiment.

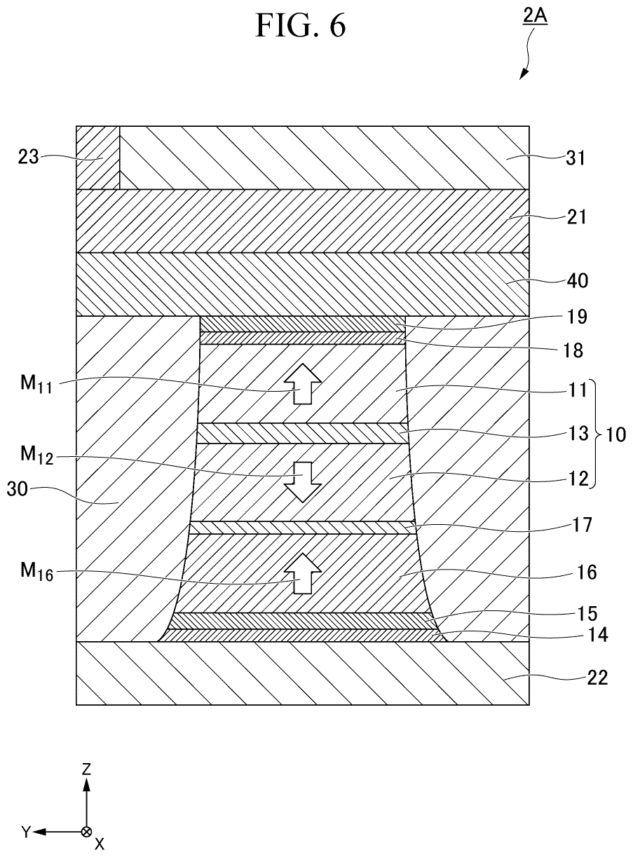

For example, FIG. 6 is a sectional view of the vicinity of a second element 2A of a light sensing device according to a first modified example of the first embodiment. The light reflecting layer 40 of the second element 2A is provided between the first electrode 21 and the photosensitive layer 10. In this case, since the light reflecting layer 40 reflects light incident on the photosensitive layer 10, it is possible to achieve the same effects as in the second element 2.

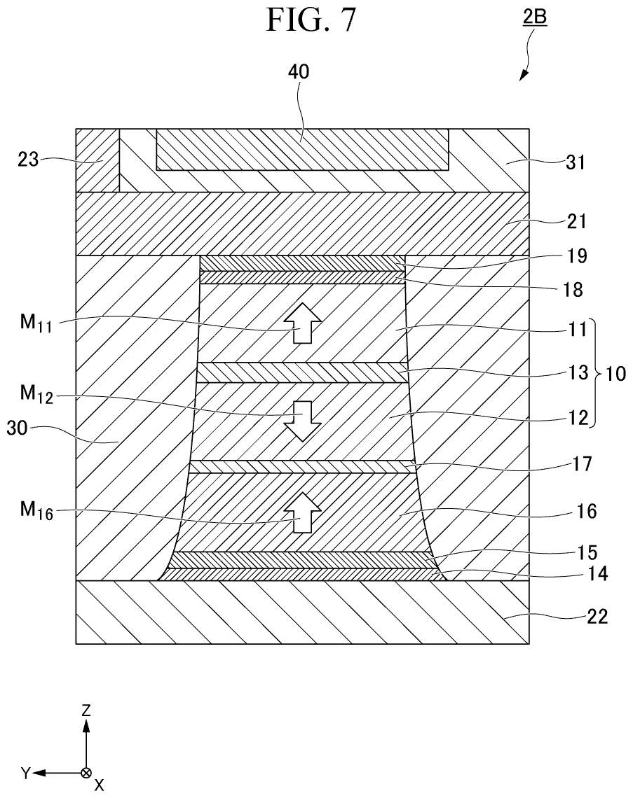

For example, FIG. 7 is a sectional view of the vicinity of a second element 2B of a light sensing device according to a second modified example of the first embodiment. The light reflecting layer 40 of the second element 2B is not in direct contact with the first electrode 21, and a part of the insulating layer 31 is provided between the light reflecting layer 40 and the first electrode 21. In this case, since the light reflecting layer 40 reflects light incident on the photosensitive layer 10, it is possible to achieve the same effects as in the second element 2.

### Second Embodiment

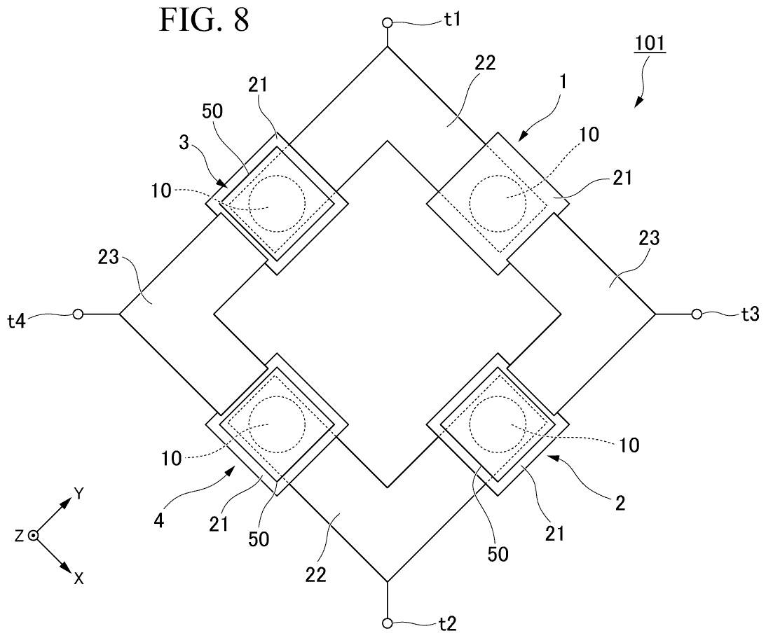

FIG. 8 is a plan view of a light sensing device 101 according to a second embodiment. The light sensing device 101 is different from the light sensing device 100 in that a light absorbing layer 50 is provided instead of the light reflecting layer 40. In the light sensing device 101, the same constituents as in the light sensing device 100 will be referred to by the same reference signs, and description thereof will be omitted.

The second element 2, the third element 3, and the fourth element 4 include the light absorbing layer 50. On the other hand, the first element 1 does not include the light absorbing layer 50. The light absorbing layer 50 is located at positions overlapping the photosensitive layers 10 of the second element 2, the third element 3, and the fourth element 4 when seen in the Z direction. The light absorbing layers 50 cover the photosensitive layers 10 of the second element 2, the third element 3, and the fourth element 4 when seen in the Z direction.

The light absorbing layer 50 absorbs light applied to the optical sensor. The light absorbing layer 50 is formed of, for example, a blackened film of copper and aluminum or graphite. Since the first element 1 does not include a light absorbing layer 50, the photosensitive layer 10 of the first element 1 is irradiated with light to be measured. The first element 1 converts a state of light applied to the first element 1 or a change of the state to an electrical signal. Since the second element 2, the third element 3, and the fourth element 4 include the light absorbing layer 50, the photosensitive layers 10 of the second element 2, the third element 3, and the fourth element 4 are not irradiated with light to be measured.

It is preferable that the light absorbing layer 50 be in contact with the upper electrode 23. The light absorbing layer 50 may receive light and generate heat. When the light absorbing layer 50 is in contact with the upper electrode 23, heat generated in the light absorbing layer 50 can be efficiently dissipated into the upper electrode 23.

The light sensing device 101 according to the second embodiment achieves the same effects as in the light sensing device 100 according to the first embodiment. The same modified examples as the light sensing device 100 can be applied to the light sensing device 101, and the light absorbing layer 50 may be disposed at the positions of the light reflecting layer 40 in the first modified example and the second modified example.

### Third Embodiment

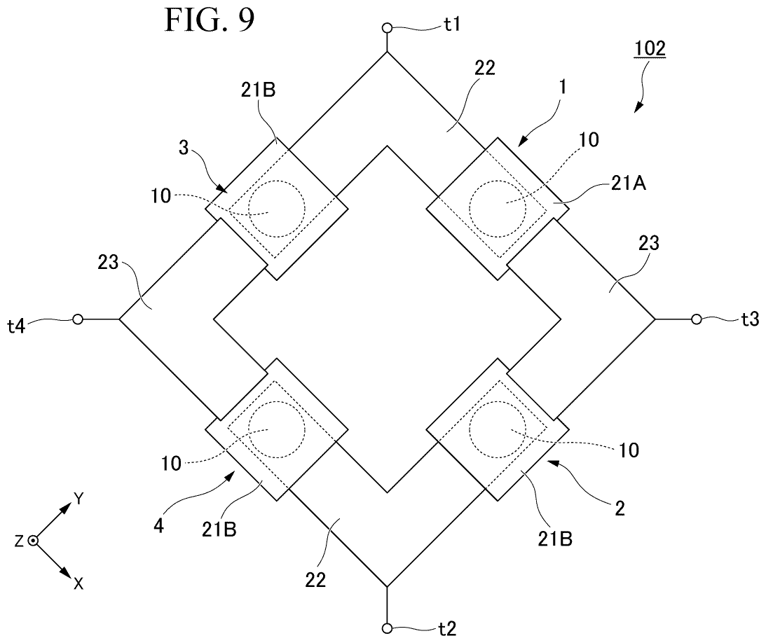

FIG. 9 is a plan view of a light sensing device 102 according to a third embodiment. The light sensing device 102 is different from the light sensing device 100 in that the light reflecting layer 40 is not provided and a first electrode 21A and a first electrode 21B are used instead of the first electrode 21. In the light sensing device 102, the same constituents as in the light sensing device 100 will be referred to by the same reference signs, and description thereof will be omitted.

The first electrode 21A is disposed on a side on which incident light is incident on the first element 1. Incident light is applied from the first electrode 21A side to the photosensitive layer 10. The first electrode 21A is formed of a conductive material. The first electrode 21A is, for example, a transparent electrode having transmissivity to light in a use wavelength band. For example, it is preferable that the first electrode 21A transmit 80% or more of light in the use wavelength band. The same material as the first electrode 21 can be used for the first electrode 21A.

The first electrode 21B is disposed on a side on which incident light is incident on each of the second element 2, the third element 3, and the fourth element 4. Incident light is applied from the first electrode 21B side to the photosensitive layer 10 in each element. The first electrode 21B is a metal electrode. The first electrode 21B reflects the incident light. The incident light is reflected by the first electrode 21B and is not incident on the photosensitive layers 10 of the second element 2, the third element 3, and the fourth element 4. The same material as the second electrode 22 can be used for the first electrode 21B.

The light sensing device 102 according to the third embodiment achieves the same effects as in the light sensing device 100 according to the first embodiment. With the light sensing device 102 according to the third embodiment, the light reflecting layer 40 does not need to be installed, and the number of constituent components of the light sensing device 102 is small.

### Fourth Embodiment

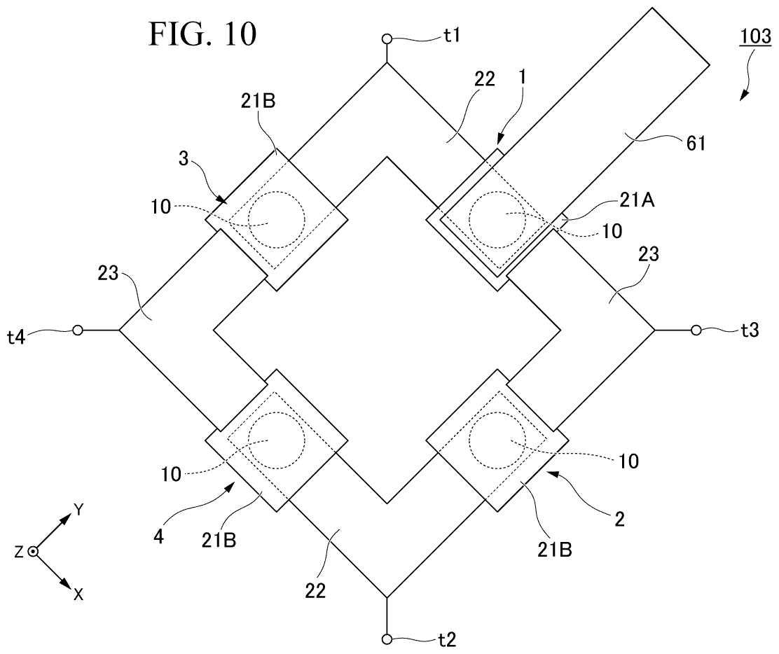

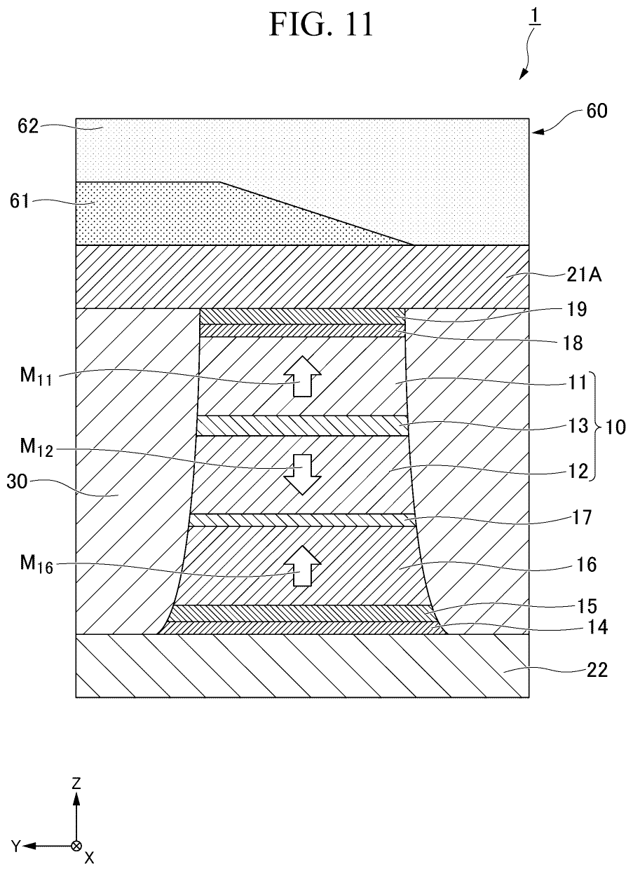

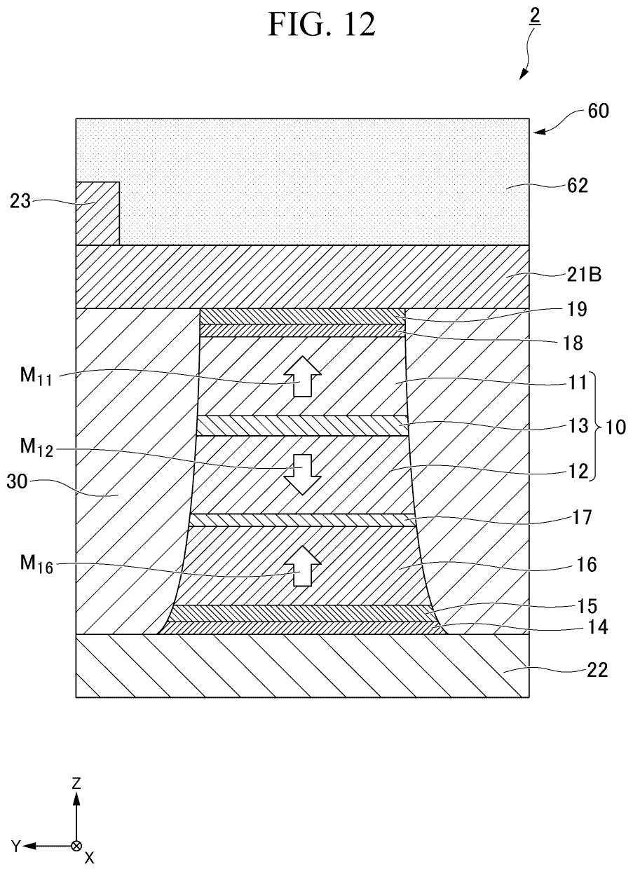

FIG. 10 is a plan view of a light sensing device 103 according to a fourth embodiment. FIG. 11 is a sectional view of the vicinity of a first element 1 of the light sensing device 103 according to the fourth embodiment. FIG. 12 is a sectional view of the vicinity of a second element 2 of the light sensing device 103 according to the fourth embodiment. The light sensing device 103 is different from the light sensing device 102 in that a light waveguide 60 is provided. In the light sensing device 103, the same constituents as in the light sensing device 102 will be referred to by the same reference signs, and description thereof will be omitted.

The light waveguide 60 includes a core 61 and a clad 62. In FIG. 10, the clad 62 is not illustrated. The light waveguide 60 fully reflects light due to a refractive index difference between the core 61 and the clad 62. Light propagates in the core 61. A first end of the core 61 is irradiated, for example, with light from a laser diode. A second end of the core 61 is connected to the first element 1. The clad 62 covers the core 61.

The core 61 includes, for example, lithium niobate as a main component. Some elements of lithium niobate may be replaced with other elements. The clad 62 is formed of, for example, SiO₂, Al₂O₃, MgF₂, La₂O₃, ZnO, HfO₂, MgO, Y₂O₃, CaF₂, or In₂O₃ or a mixture thereof. The material of the core 61 and the material of the clad 62 are not limited to these examples. For example, the core 61 may be formed of a material in which germanium oxide is added to silicon or silicon oxide, and the clad 62 may be formed of silicon oxide. For example, the core 61 may be formed of tantalum oxide (Ta₂O₅), and the clad 62 may be formed of silicon oxide or aluminum oxide.

Light propagating in the core 61 is applied to only the first element 1 and is not applied to the second element 2, the third element 3, and the fourth element 4. Accordingly, the photosensitive layer 10 of the first element 1 is irradiated with light to be measured, and the photosensitive layers 10 of the second element 2, the third element 3, and the fourth element 4 are not irradiated with light to be measured.

The light sensing device 103 according to the fourth embodiment achieves the same effects as in the light sensing device 100 according to the first embodiment. With the light sensing device 103, when ambient light other than light propagating in the core 61 can be shut out, the first electrode 21B may be replaced with a transparent electrode.

### Fifth Embodiment

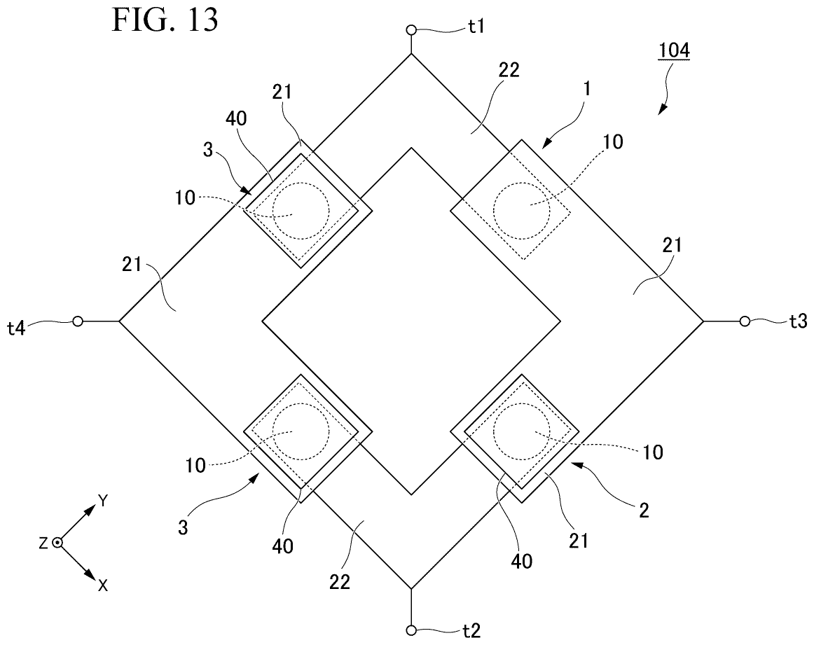

FIG. 13 is a plan view of a light sensing device 104 according to a fifth embodiment. The light sensing device 104 is different from the light sensing device 100 in that the upper electrode 23 is not provided and the first electrode 21 also has the function of the upper electrode 23. In the light sensing device 104, the same constituents as in the light sensing device 100 will be referred to by the same reference signs, and description thereof will be omitted.

The first electrode 21 extends over the first element 1 and the second element 2. Similarly, the first electrode 21 extends over the third element 3 and the fourth element 4. The first electrode 21 connected to the first element 1 and the second element 2 is connected to the third terminal t3. The first electrode 21 connected to the third element 3 and the fourth element 4 is connected to the fourth terminal t4.

The light sensing device 104 according to the fifth embodiment achieves the same effects as in the light sensing device 100 according to the first embodiment. With the light sensing device 104 according to the fifth embodiment, the upper electrode 23 does not need to be installed, and the number of constituent components of the light sensing device 104 is small.

### Sixth Embodiment

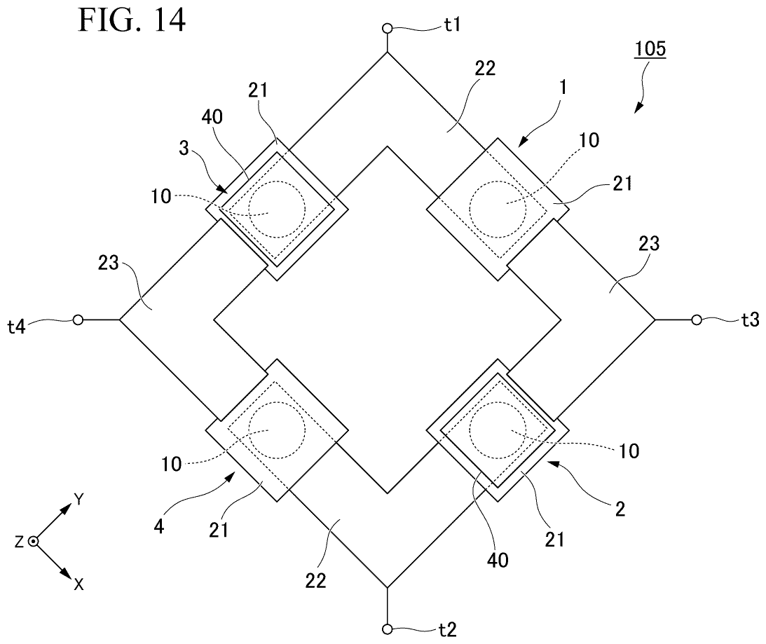

FIG. 14 is a plan view of a light sensing device 105 according to a sixth embodiment. The light sensing device 105 is different from the light sensing device 100 in that the light reflecting layer 40 is not provided in the fourth element 4. In the light sensing device 105, the same constituents as in the light sensing device 100 will be referred to by the same reference signs, and description thereof will be omitted.

The second element 2 and the third element 3 include a light reflecting layer 40. On the other hand, the first element 1 and the fourth element 4 do not include a light reflecting layer 40. The light reflecting layer 40 is located at positions overlapping of the photosensitive layers 10 of the second element 2 and the third element 3 when seen in the Z direction. The light reflecting layers 40 cover the photosensitive layers 10 of the second element 2 and the third element 3 when seen in the Z direction.

Since the first element 1 and the fourth element 4 do not include a light reflecting layer 40, the photosensitive layers 10 of the first element 1 and the fourth element 4 are irradiated with light to be measured. The first element 1 and the fourth element 4 converts a state of light applied to the first element 1 and the fourth element 4 or a change of the state to an electrical signal. Since the second element 2 and the third element 3 include the light reflecting layer 40, the photosensitive layers 10 of the second element 2 and the third element 3 are not irradiated with light to be measured.

The light sensing device 105 according to the sixth embodiment achieves the same effects as in the light sensing device 100 according to the first embodiment.

When the resistance value of the first element 1 is defined as R_{A}, the resistance value of the second element 2 is defined as R_{B}, the resistance value of the third element 3 is defined as R_{C}, and the resistance value of the fourth element 4 is defined as R_{D}, the bridge circuit satisfies a relationship of R_{C}/R_{D}−R_{A}/R_{B} when the potential difference between the third terminal t3 and the fourth terminal t4 is 0. That is, R_{C}×R_{B}=R_{A}×R_{D} is satisfied. The left side is a product of the resistance values of the second element 2 and the third element 3 which are not irradiated with light and does not change with an influence other than disturbance. When the light sensing device 105 is irradiated with light to be measured, R_{A} and R_{D} change. Accordingly, the light sensing device 105 can cause an output which doubles that of the light sensing device 100.

An example in which the light reflecting layer 40 is provided in the second element 2 and the third element 3 has been described above, but the light reflecting layer 40 may be replaced with the light absorbing layer 50 similarly to the second embodiment. Similarly to the third embodiment, the first electrode 21 of the second element 2 and the third element 3 may be replaced with the first electrode 21B reflecting light. Similarly to the fourth embodiment, the light waveguide 60 may be provided, and light propagating in the core 61 may be applied to only the photosensitive layers 10 of the first element 1 and the fourth element 4. Similarly to the fifth embodiment, the first electrode 21 may also be used as the upper electrode 23.

While some embodiments and modified examples have been described above and specific configurations of a light sensing device have been described above, the light sensing device according to the present disclosure is not limited to these examples. The light sensing device according to the present disclosure can be modified in various forms within a range in which the advantageous effects of the present disclosure are satisfied. For example, featured configurations of the embodiments and the modified examples may be combined.

The light sensing devices according to the aforementioned embodiments and the modified examples can be used for various purposes. The following light sensing device 100 can be replaced with the light sensing devices 101, 102, 103, 104, and 105.

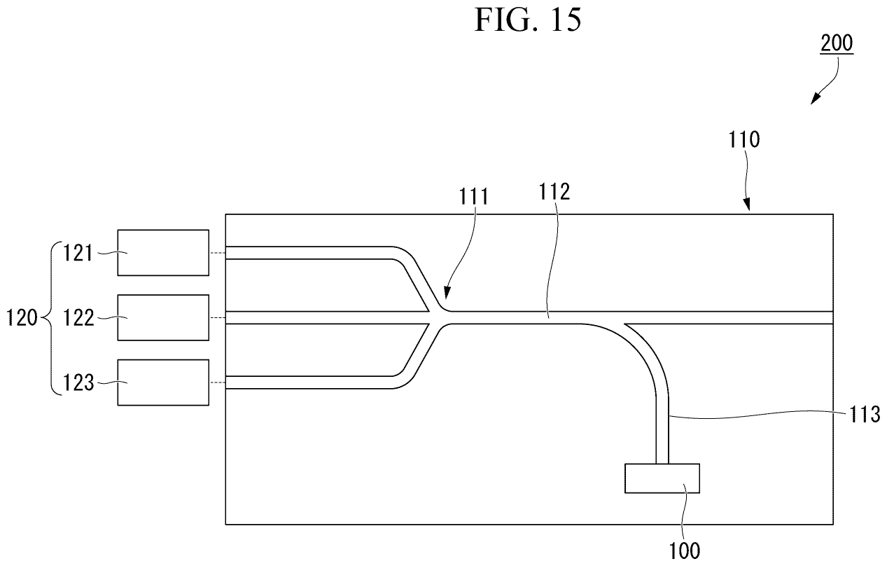

FIG. 15 is a diagram schematically illustrating an optical unit 200 according to a first application example. The optical unit 200 illustrated in FIG. 15 includes a waveguide unit 110 and a light source 120. The waveguide unit 110 includes the aforementioned light sensing device 100 and a waveguide 111. The waveguide 111 includes an output waveguide 112 and a monitoring waveguide 113. The output waveguide 112 is a waveguide for outputting light from the light source 120 to the outside. The monitoring waveguide 113 is a waveguide for divisionally outputting a part of light propagating in the output waveguide 112 to the light sensing device 100. The monitoring waveguide 113 allows light to propagate to the light sensing device 100.

The light source 120 is, for example, a laser light source. The light source 120 includes, for example, a red laser 121, a green laser 122, and a blue laser 123. Light output from the light source 120 propagates in the output waveguide 112 and is output to the outside. A part of light output from the light source 120 propagates in the monitoring waveguide 113 and reaches the light sensing device 100.

The optical unit 200 outputs laser light to the outside while monitoring the output from the light source 120 using the light sensing device 100. The optical unit 200 can adjust white balance of light output from the output waveguide 112 to the outside by adjusting the intensity of light output from the lasers.

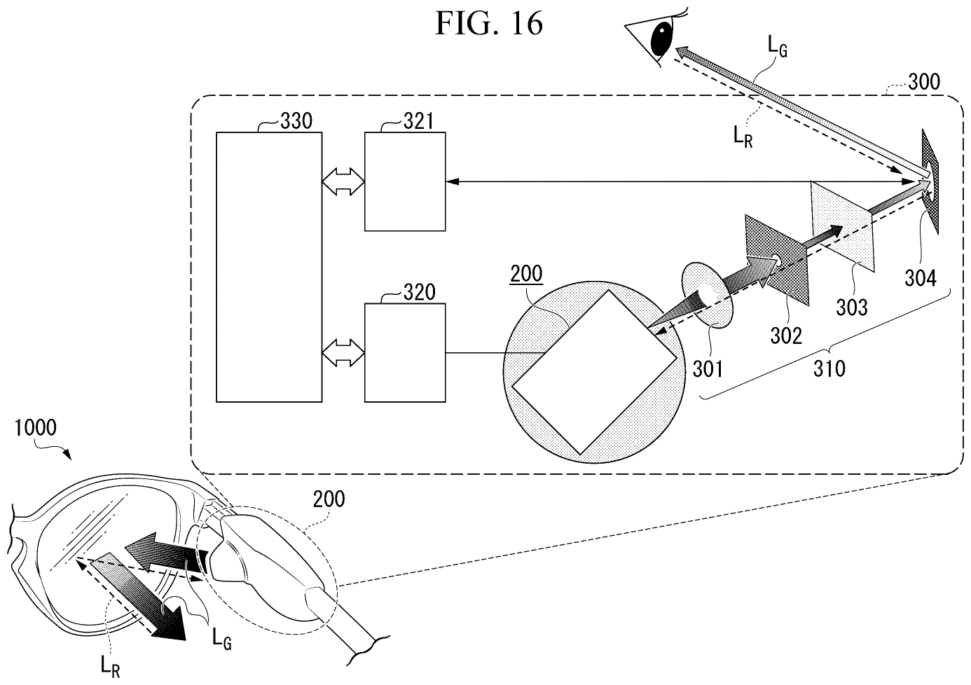

FIG. 16 is a conceptual diagram of an optical system 300 using the optical unit 200. The optical system 300 can be mounted, for example, in an eyeglass 1000.

The optical system 300 includes the optical unit 200, an optical system 310, drivers 320 and 321, and a controller 330. The optical system 310 includes, for example, a collimator lens 301, a slit 302, an ND filter 303, and an optical scanning mirror 304. The optical system 310 guides light output from the optical unit 200 to an irradiation subject (an eye in this example). The optical scanning mirror 304 is, for example, a two-axis MEMS mirror that changes a reflecting direction of laser light to a horizontal direction and a vertical direction. The optical system 310 is an example and is not limited to this example. The driver 320 controls the output from the light source 120 of the optical unit 200. The driver 321 is a control system for moving the optical scanning mirror 304. The controller 330 controls the drivers 320 and 321.

Light L_{G} output from the light source 120 of the optical unit 200 propagates in the optical system 310, is reflected by a lens of the eyeglass 1000, and is incident on an eye. In this example, light is reflected by the lens of the eyeglass 1000, but light may be directly applied to the eye.

Light L_{G} of red, green, and blue emitted from the light source 120 displays an image. The image can be freely controlled. Output intensities of the red layer 121, the green laser 122, and the blue laser 123 can be adjusted on the basis of measurement results of an output from the light sensing device 100 which is irradiated with visible light output from the red layer 121, the green laser 122, and the blue laser 123.

By using this optical system 300, it is possible to project an image onto the eyeglass 1000. By monitoring the intensity of projected light using the light sensing device 100, it is possible to adjust color tones of an image.

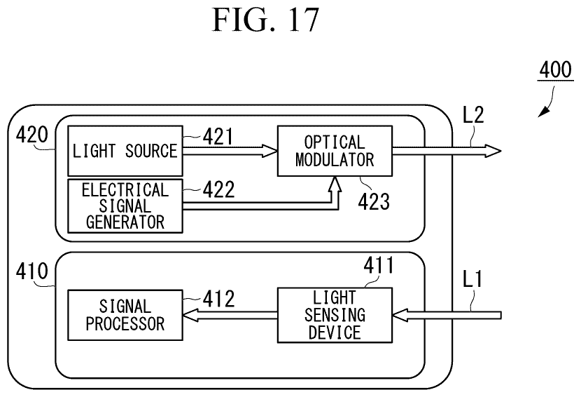

FIG. 17 is a block diagram illustrating a transceiver device 400 according to a second application example. The transceiver device 400 includes a receiver device 410 and a transmitter device 420. The receiver device 410 receives an optical signal L1, and the transmitter device 420 transmits an optical signal L2.

The receiver device 410 includes, for example, a light sensing device 411 and a signal processor 412. The aforementioned light sensing device 100 can be used as the light sensing device 411. In the receiver device 410, for example, a light pulse is applied to the light sensing device 411. The optical signal L1 includes a light pulse. The light sensing device 411 converts the optical signal L1 to an electrical signal. The signal processor 412 processes the electrical signal which is a conversion result from the light sensing device 411. The signal processor 412 receives a signal included in the optical signal L1 by processing the electrical signal from the light sensing device 411. The receiver device 410 receives a signal included in the optical signal L1 on the basis of an output signal from the light sensing device 411.

The transmitter device 420 includes, for example, a light source 421, an electrical signal generator 422, and an optical modulator 423. The light source 421 is, for example, a laser unit. The light source 421 may be provided outside of the transmitter device 420. The electrical signal generator 422 generates an electrical signal on the basis of transmission information. The electrical signal generator 422 may form a unified body along with a signal converter in the signal processor 412. The optical modulator 423 modulates light output from the light source 421 on the basis of the electrical signal generated by the electrical signal generator 422 and outputs the optical signal L2.

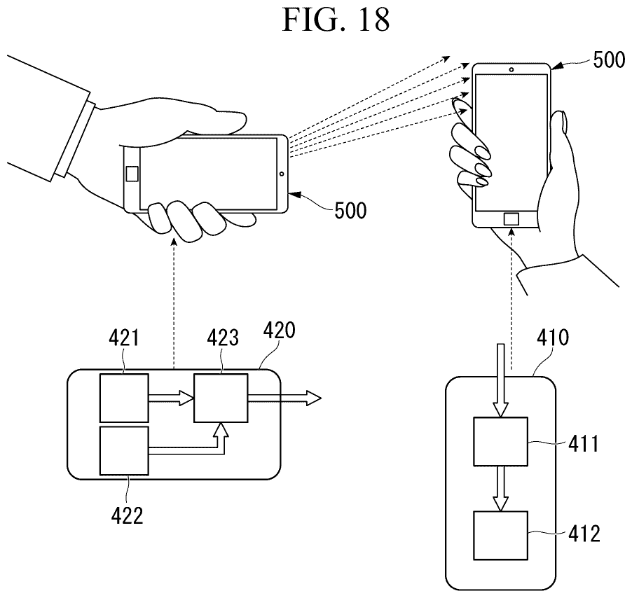

FIG. 18 is a conceptual diagram illustrating an example of a communication system. The communication system illustrated in FIG. 18 includes two terminal devices 500. The terminal devices 500 are, for example, smartphones, tablets, or personal computers.

Each terminal device 500 includes the receiver device 410 and the transmitter device 420. An optical signal transmitted from the transmitter device 420 of one terminal device 500 is received by the receiver device 410 of the other terminal device 500. Light used in transmission and reception between the terminal devices 500 is, for example, visible light. The receiver device 410 includes the light sensing device 411.

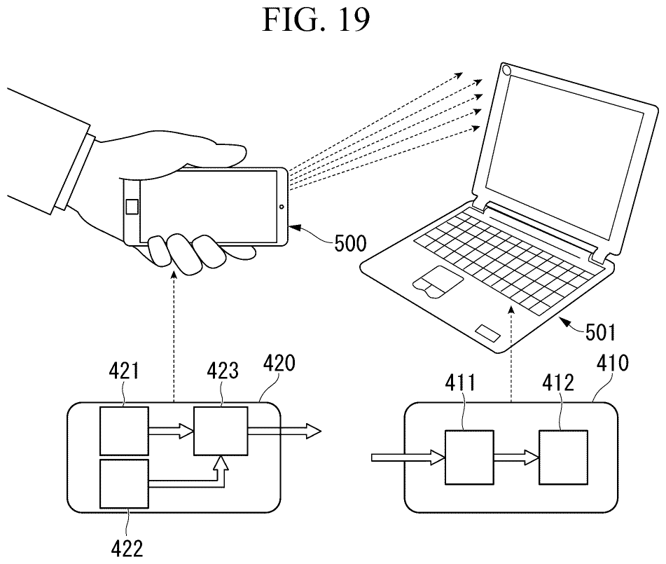

FIG. 19 is a conceptual diagram illustrating an example of a communication system. In the example illustrated in FIG. 18, both the terminal devices 500 are smartphones, but the terminal devices 500 may be different between a transmitting side and a receiving side. For example, a terminal device 500 illustrated in FIG. 19 is a smartphone, and a terminal device 501 is a personal computer.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

### EXPLANATION OF REFERENCES

1 First element
2, 2A, 2B Second element
3 Third element
4 Fourth element
10 Photosensitive layer
11 First ferromagnetic layer
12 Second ferromagnetic layer
13 Spacer layer
14 Buffer layer
15 Seed layer
16 Third ferromagnetic layer
17 Magnetic coupling layer
18 Perpendicular magnetization inducing layer
19 Cap layer
21, 21A, 21B First electrode
22 Second electrode
23 Upper electrode
30, 31 Insulating layer
40 Light reflecting layer
50 Light absorbing layer
60 Light waveguide
61 Core
62 Clad
100, 101, 102, 103, 104, 105 Light sensing device
110 Waveguide unit
111 Waveguide
112 Output waveguide
113 Monitoring waveguide
120 Light source
121 Red laser
122 Green laser
123 Blue laser
200 Optical unit
300 Optical system
301 Collimator lees
302 Slit
303 ND filter
304 Optical scanning mirror
310 Optical system
320, 321 Driver
330 Controller
400 Transceiver device
410 Receiver device
411 Light sensing device
412 Signal processor
420 Transmitter device
421 Light source
422 Electrical signal generator
423 Optical modulator
500, 501 Terminal device
1000 Eyeglass
t1 First terminal
t2 Second terminal
t3 Third terminal
t4 Fourth terminal

What is claimed is:

1. A light sensing device comprising a first terminal, a second terminal, a third terminal, a fourth terminal, a first element, a second element, a third element, and a fourth element,
wherein the first terminal, the first element, the second element, and the second terminal form a first path,
wherein the first terminal, the third element, the fourth element, and the second terminal form a second path,
wherein the third terminal is connected between the first element and the second element,
wherein the fourth terminal is connected between the third element and the fourth element,
wherein each of the first element, the second element, the third element, and the fourth element includes a first electrode, a second electrode, and a photosensitive layer that is provided between the first electrode and the second electrode and configured to generate a voltage in a case where light is applied to the photosensitive layer,
wherein the photosensitive layer of the first element is irradiated with light to be measured, and
wherein the photosensitive layers of the second element and the third element are not irradiated with the light to be measured.

2. The light sensing device according to claim 1, wherein the photosensitive layer of the fourth element is not irradiated with the light to be measured.

3. The light sensing device according to claim 1, wherein the photosensitive layer of the fourth element is irradiated with the light to be measured.

4. The light sensing device according to claim 1, wherein the first electrode of the first element is a transparent electrode, and
wherein the first electrodes of the second element and the third element are metal electrodes.

5. The light sensing device according to claim 1, wherein the first electrode of each of the first element, the second element, the third element, and the fourth element is a transparent electrode, and
wherein each of the second element and the third element further includes a light reflecting layer at a position overlapping the photosensitive layer in a case where seen in a stacking direction.

6. The light sensing device according to claim 1, wherein the first electrode of each of the first element, the second element, the third element, and the fourth element is a transparent electrode, and
wherein each of the second element and the third element further includes a light absorbing layer at a position overlapping the photosensitive layer in a case where seen in a stacking direction.

7. The light sensing device according to claim 1, further comprising a light waveguide that covers the first element, the second element, the third element, and the fourth element,
wherein the light waveguide includes a core in which light propagates and a clad which covers the core, and
wherein light propagating in the core is applied to the first element.

8. The light sensing device according to claim 1, wherein the photosensitive layer includes a first ferromagnetic layer, a second ferromagnetic layer, and a spacer layer located between the first ferromagnetic layer and the second ferromagnetic layer.
